(19) United States
(12) Patent Application Publication
(10) Pub. No.: US 2004/0183397 A1
(43) Pub. Date: Sep. 23, 2004

(54) Surface acoustic wave device

(76) Inventors: Chan Hin Kam, Singapore (SG); Yee Loy Lam, Singapore (SG); Yan Zhou, Singaporean (SG); Shide Cheng, Pleasanton, CA (US); Woon Siong Gan, Singapore (SG)

Correspondence Address: BOWDITCH & DEWEY, LLP, 161 WORCESTER ROAD, P.O. BOX 9320, FRAMINGHAM, MA, 01701-9320, US

(21) Appl. No.: 10/296,412

(22) PCT Filed: May 29, 2001
(86) PCT No.: PCT/SG01/00086

(51) Int. Cl. H03H 9/145

(52) U.S. Cl. 310/313 R

(57) ABSTRACT

A surface acoustic wave device which can generate surface acoustic waves in at least two directions. The device includes a piezoelectric layer, an elastic substrate and an electrode layer which includes two arrays 23 and 24 of linear electrodes with gap regions 25 located between the electrodes. Alternatively, the electrode layer may be patterned as an array of concentric annular strips for the generation of annular surface acoustic waves.

This invention relates to surface acoustic wave (SAW) devices, and more particularly to the electrode structure design of a two-dimensional SAW device based on piezoelectric thin films.

SAW devices and related subject matter are described in the following publications:

U.S. Pat. No. 3,955,160;

U.S. Pat. No. 4,437,031;

U.S. Pat. No. 4,456,847;

U.S. Pat. No. 4,491,811;

U.S. Pat. No. 4,507,581;

U.S. Pat. No. 4,531,107;

Dransfield et al., “Excitation, Detection and Attenuation of High-Frequency Elastic Surface Waves”, Physical Acoustics, Principles and Methods, W. P. Mason and R. N. Thurston ed., Vol. VII, pp. 219-272, Academic Press, 1970;

Day et al., “Annular Piezoelectric Surface Waves”, IEEE Transactions on Sonics and Ultrasonics, Vol. SU-19, No. 4, pp. 461-466, October 1972; and

Shih et al., “Theoretical Investigation of the SAW properties of Ferroelectric Film Composite Structures”, IEEE Transactions on Ultrasonics, Ferroelectrics, and Frequency Control, Vol. 45, No. 2, pp. 305-316, March 1998.

A SAW device is constructed so that electrical signals are transformed into acoustic surface waves by a transducer formed on a piezoelectric substrate, and the acoustic surface waves propagate on the surface of the substrate. The device is fabricated using piezoelectric materials, such as a piezoelectric crystal, LiNbO₃, Quartz, etc., piezoelectric ceramic material, Pb(ZrTi)O₃ (PZT), ZnO, etc., or a piezoelectric thin film deposited on a non-piezoelectric substrate, such as ZnO on silicon. The SAW device comprises a pair of electro-SAW transducers and a SAW propagation path established therebetween. Usually; the SAW propagation path is constituted by a part of the polished piezoelectric substrate which is used in common for both transducers.

An acoustic wave with a frequency as high as several gigahertz travels on the substrate surface at a velocity which is about 10⁻⁵ times that of electromagnetic waves. A surface acoustic wave thus has the slow travel property of sound while retaining the microwave frequency of its source. SAW devices utilizing these properties can be used in delay lines, filters, pulse processors and other microwave devices and circuits.

In a SAW delay line, the delay time is determined by the velocity of the surface acoustic wave and the distance travelled by the surface acoustic wave on a piezoelectric surface.

In a SAW filter, the frequency characteristics of the filter are determined mainly by the sound velocity of the SAW and the electrode patterns of the input and output transducers.

Generally, the electrode pattern of a transducer includes a plurality of parallel electrode strips. The orientation of the strips determines the direction of a wave front.

In a single-phase transducer, all the electrode strips are maintained at a single phase, with one electrode strip and one gap region between electrode strips defining a region for one wavelength.

In an interdigital transducer, electrode strips are formed at an interval of ½ wavelength, and two-phase control is carried out. More particularly, two comb-shaped electrodes each having a plurality of electrode fingers (strips) are opposed and interlocked and maintained at opposite phases. Two electrode strips and two gap regions between the strips define a region for one wavelength. Typically, the electrode strips and the gap regions all have the same width l which is λ/4, where λ represents the wavelength of a SAW.

Conventional transducers generate surface acoustic waves one-dimensionally, that is, the surface acoustic wave travels generally in only one direction. An object of the invention is to develop a new type of SAW device that can generate two-dimensional surface acoustic waves.

According to the invention, there is provided an electrode layer for a two-dimensional surface acoustic wave device, comprising an electrode pattern of alternating conductive and non-conductive gap regions in at least two directions.

The electrode pattern may comprise first and second arrays of substantially linear parallel strips of conductive material, the strips of the first array oriented at an angle with respect to the strips of the second array. The angle of orientation may be 90 degrees.

The electrode pattern may comprise an array of concentric annular conductive strips.

The width of the conductive strips may be approximately equal to the separation between the strips.

According to a second aspect of the invention, there is provided a two-dimensional surface acoustic wave device including the patterned electrode layer.

The patterned electrode layer may be a top electrode layer located on the piezoelectric layer. The device may include an underlay electrode layer located between the piezoelectric layer and the substrate layer.

The patterned electrode layer may be an underlay electrode layer located between the piezoelectric layer and the substrate layer, the device further including a top electrode layer located on the piezoelectric layer.

The device may further include a buffer layer between the underlay electrode layer and the substrate layer.

A surface acoustic wave device based on a piezoelectric thin film deposited on a non-piezoelectric substrate has been designed. The device is a single-phase device and can generate two-dimensional surface acoustic waves.

For a better understanding of the present invention, specific embodiments according to the invention will now be described, by way of example, with reference to the accompanying drawings, in which:

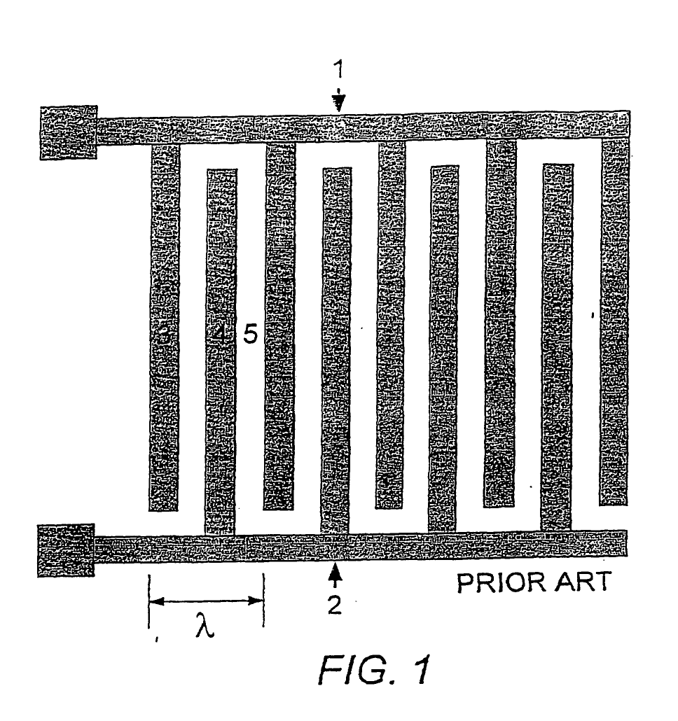

FIG. 1 is a top view of a known interdigital transducer configuration;

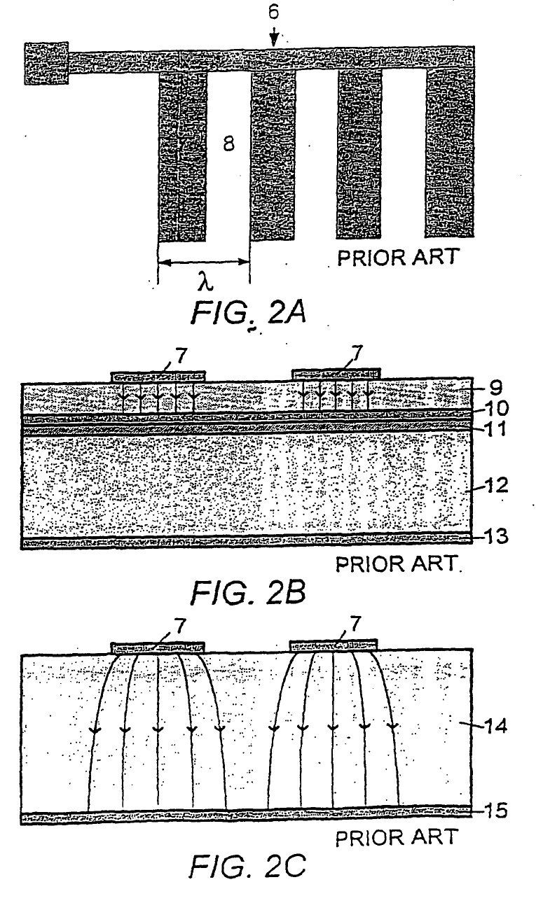

FIG. 2A is a top view of a known single-phase transducer configuration with conductive and non-conductive strips of width λ/2;

FIG. 2B is a side schematic view to illustrate a typical electric field pattern for a ZnO/Si single-phase transducer;

FIG. 2C is a side schematic view to illustrate a typical electric field pattern for a single-phase LiNbO₃ transducer;

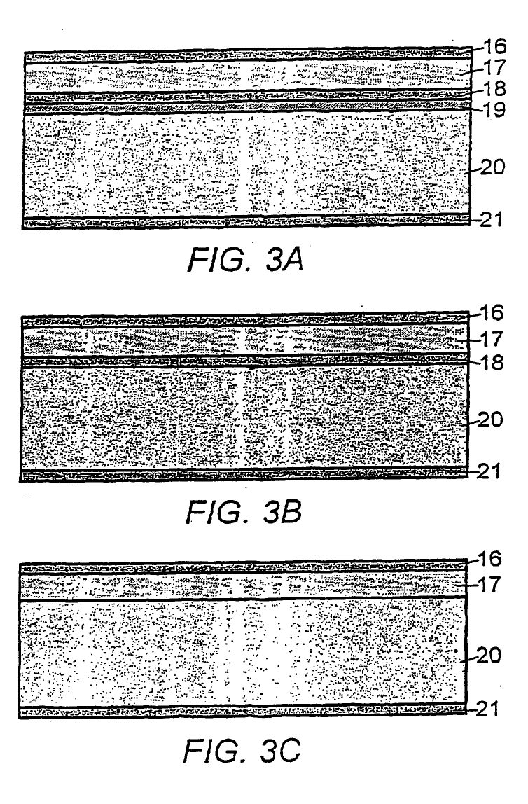

FIG. 3A is a side schematic view of a substrate that is suitable for two-dimensional SAW device fabrication;

FIG. 3B is a side schematic view of another substrate that is suitable for two-dimensional SAW device fabrication;

FIG. 3C is a side schematic view of another substrate that is suitable for two-dimensional SAW device fabrication;

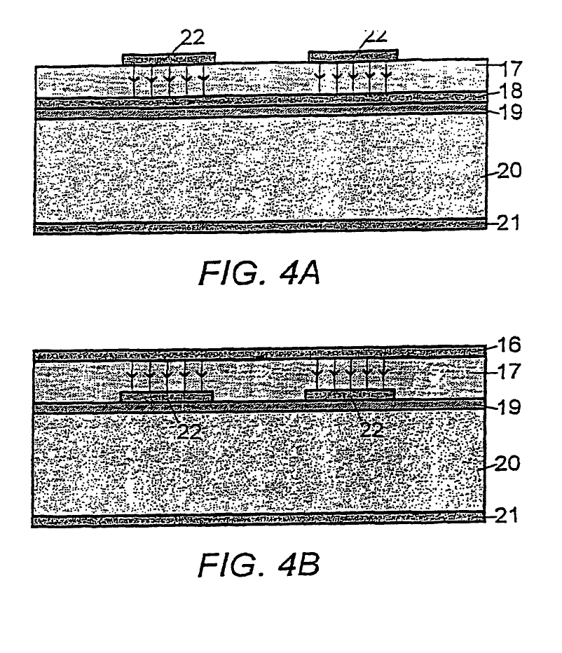

FIG. 4A is a side schematic view showing a typical electric field pattern for a first embodiment of two-dimensional SAW device;

FIG. 4B is a side schematic view showing a typical electric field pattern for a second embodiment of a two-dimensional SAW device;

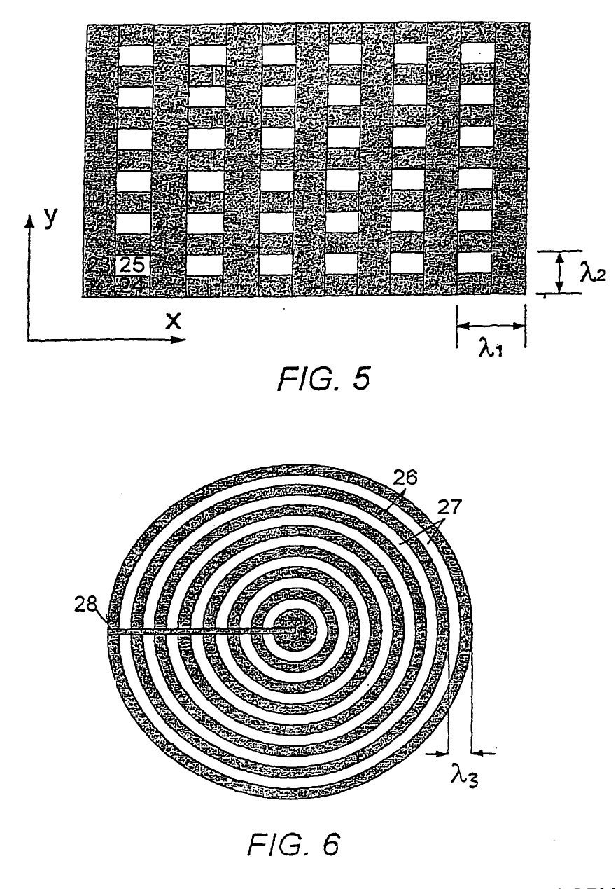

FIG. 5 is a top view of a patterned electrode layer for a two-dimensional SAW device; and

FIG. 6 is a top view of an annular patterned electrode layer for a two-dimensional SAW device.

As shown in FIG. 1, a conventional interdigital transducer consists of two electrodes 1 and 2, each comprising an arm having a plurality of conductive fingers 3 and 4. The fingers are electrode strips extending from the arm, and are alternately spaced with respect to one another along a non-conductive surface, with non-conductive gap regions 5 between the fingers. As indicated in FIG. 1, the width of each of the conductive fingers and the non-conductive gaps therebetween is equal to λ/4 where λ is the SAW wavelength. The upper limit of the operating frequency of a SAW device is determined by the capability of the photolithographic techniques being used to define the transducer.

A single-phase transducer configuration, as shown in FIG. 2A, doubles the operating frequency possible for a given photolithographic capability. In FIG. 2A, a single-phase transducer includes a conducting arm 6 having a plurality of conductive fingers 7 extending from the arm, with non-conductive gap regions 8 between the fingers. As indicated, the spacing between the fingers, as well as the width of each finger is λ/2, where λ is the SAW wavelength.

A side view of a single-phase one-dimensional transducer in a layered configuration is shown in FIG. 2B. The transducer includes a top electrode layer patterned as shown in FIG. 2A including fingers 7. Below this, the transducer includes ZnO layer 9, Al underlay electrode layer 10, SiO₂ buffer layer 11, silicon layer 12 and Al electrode layer 13. The electric field lines are generally parallel since the thickness of the ZnO layer 9 is typically three to ten times smaller than the spacing between the electrode fingers 7.

In contrast, a single-phase one-dimensional transducer in a single crystal configuration is shown in FIG. 2C. In this case, the spacing between the electrode fingers 7 is much smaller than the crystal thickness. Therefore, fringing of the electric fields occurs as depicted. In FIG. 2C, the single-phase patterned electrode layer with conductive fingers 7 is positioned on a LiNbO₃ substrate 14, and a back electrode 15 is deposited at the back side of the LiNbO₃ substrate. The inherent difference in the field pattern between the layered crystal structure and the single crystal structure makes the single-phase transducer in the layered configuration much more efficient than its counterpart in the single crystal configuration.

FIGS. 3A, 3B and 3C show side schematic views of substrates that are suitable for embodiments of two-dimensional SAW device fabrication. In FIG. 3A, the substrate includes the top electrode layer 16 (Al, Au, etc.), the piezoelectric layer 17 (ZnO, PZT, LiNbO₃, LiTaO₃, etc.), the underlay electrode layer 18 (Al, Au, etc.), the buffer layer 19 (SiO₂, Si₃N₄, diamond, etc.), the elastic substrate layer 20 (sapphire, Si, GaAs, InP, fused silica, glass, etc.),and the back electrode layer 21 (Al, Au, etc.). In FIG. 3B, the buffer layer 19 is absent, whilst in FIG. 3C, both the underlay electrode layer 18 and buffer layer 19 are absent.

The term “elastic substrate layer” means any substrate which has a linear relationship between its stress and strain. Thus, an elastic SAW can travel on it.

FIGS. 4A and 4B are side schematic views showing embodiments of two-dimensional SAW devices with typical electric field patterns.

FIGS. 5 and 6 show plan views of a patterned electrode layer for a two-dimensional SAW device.

For the first embodiment, shown in FIG. 4A, the substrate of FIG. 3A was used, with the top electrode layer 16 patterned with a two-dimensional electrode pattern 22. For example, the patterned electrode layer 22 may be patterned as shown in either FIG. 5 or FIG. 6. Underlay electrode layer 18 is unpatterned. FIG. 4A shows the electric field pattern for the first embodiment operating in single-phase mode, i.e. all the electrode pattern 22 is maintained at the same phase.

For the second embodiment, shown in FIG. 4B, the substrate of FIG. 3A was used, with the underlay electrode layer 18 patterned with a two-dimensional electrode pattern 22. For example, the patterned electrode layer 22 may be patterned as shown in either FIG. 5 or FIG. 6. The top electrode layer 16 remains unpatterned. FIG. 4B shows the electric field pattern for the second embodiment operating in single-phase mode, i.e. all the electrode pattern 22 is maintained at the same phase.

The patterned electrode layer shown in FIG. 5 comprises two arrays 23 and 24 of linear strip electrodes with gap regions 25 located between the electrodes. The arrays 23 and 24 are in electrical contact with each other, and consequently the patterned electrode layer may be fabricated using standard photolithography and metallization processes. In the embodiment, the arrays 23 and 24 are oriented at 90 degrees to each other. Thus, the arrays 23 and 24 define two different ultrasonic wavelengths λ₁ and λ₂ that propagate simultaneously in the x and y directions respectively.

The arrays 23 and 24 are at the same electrical potential, and respond (resonate) at different frequencies of an electrical power source. Two surface acoustic waves may be created by providing an electrical source which contains two frequency components. If the electrical source only contains one frequency component then only one surface acoustic wave can be created, unless the arrays define the same ultrasonic wavelength.

The design of the patterned electrode layer of FIG. 5 may be generalised, with two or more electrode arrays positioned at different angles and with the linear electrodes having a different width, to generate ultrasonic waves in different directions and with different wavelengths.

The patterned electrode layer shown in FIG. 6 comprises an array of concentric annular electrode strips 26 separated by gap regions 27. The electrode layer pattern defines radial ultrasonic waves of wavelength λ₃. The annular electrode strips 26 are in electrical connection with each other by means of a radial strip 28.

In general, a two-dimensional single-phase SAW device may be fabricated using any of the substrates illustrated in FIGS. 3A to 3C. Either the top electrode layer 16 or the underlay electrode layer 18 is patterned, for example, in the manner illustrated in FIGS. 5 and 6.

The piezoelectric layer 17 may be a polycrystalline or single crystal material. The piezoelectric layer 17 may be formed of, for example, ZnO, PZT, LiNbO₃, LiTaO₃, etc.

The buffer layer 19 is a dielectric thin film, such as SiO₂, Si₃N₄, diamond film, etc. This layer is generally included to improve the crystallinity or texture of the piezoelectric layer. It can also be used to increase the speed of the SAW.

Each electrode layer may be a thin metal film such as Al, Au, Ag, Ti, or a conductive thin oxide film, such as Al:ZnO, ITO, ATO, or a semiconductor film, such as p-type silicon.

The elastic substrate layer 20 may be a crystalline material, such as sapphire, SrTiO₃, etc. or a non-crystalline, acoustically isotropic material, such as fused silica, glass, etc. or a conductive material such as Si, Ge, GaAs, InP, AlN, GaN, etc. or a semiconductor material such as ZnO, PZT, LiNbO₃, LiTaO₃, etc.

In the case where a two-dimensional SAW device is fabricated using the substrate of FIG. 3C, then the substrate layer will be either a conductive or semiconductor material, and the top electrode layer will be patterned.

These two-dimensional SAW devices can use the substrate more efficiently and are more versatile than conventional SAW devices, and can be used in SAW delay lines, resonators and filters. By using semiconductors as the substrate, it is also possible to integrate SAW devices and electrical circuits on the same chip.

1. An electrode layer for a two-dimensional surface acoustic wave device, comprising an electrode pattern of alternating conductive and non-conductive regions in at least two directions.

2. An electrode structure according to claim 1, the electrode pattern comprising first and second arrays of substantially linear parallel strips of conductive material, the strips of the first array oriented at an angle with respect to the strips of the second array.

3. An electrode structure according to claim 2, the angle being 90 degrees.

4. An electrode structure according to claim 1, the electrode pattern comprising an array of concentric annular conductive strips.

5. An electrode structure according to any one of claims 2 to 4, the width of the conductive strips being approximately equal to the separation between the strips.

6. A two-dimensional surface acoustic wave device comprising a piezoelectric layer, an elastic substrate layer and an electrode layer patterned according to any one of claims 1 to 5.

7. A two-dimensional surface acoustic wave device according to claim 6, the patterned electrode layer being a top electrode layer located on the piezoelectric layer.

8. A two-dimensional surface acoustic wave device according to claim 7, including an underlay electrode layer located between the piezoelectric layer and the substrate layer.

9. A two-dimensional surface acoustic wave device according to claim 6, the patterned electrode layer being an underlay electrode layer located between the piezoelectric layer and the substrate layer, the device further including a top electrode layer located on the piezoelectric layer.

10. A two-dimensional surface acoustic wave device according to claim 8 or 9, further including a buffer layer between the underlay electrode layer and the substrate layer.
